(19) United States
(12) Patent Application Publication
(10) Pub. No.: US 2024/0354624 A1
(43) Pub. Date: Oct. 24, 2024

(54) RADIATION SHIELDING

(71) Applicant: Wisconsin Alumni Research Foundation, Madison, WI (US)

(72) Inventors: Elena D'Onghia, Madison, WI (US); Paolo Desiati, Madison, WI (US); Kieran Furlong, Madison, WI (US)

(21) Appl. No.: 18/578,086

(22) PCT Filed: Jul. 15, 2022
(86) PCT No.: PCT/US2022/037286

§ 371 Date: Jan. 10, 2024

Related U.S. Application Data
(60) Provisional application No. 63/222,315, filed on Jul. 15, 2021.

(51) Int. Cl. G06N 10/40; G21F 7/06; H05K 9/00

(52) U.S. Cl. CPC G06N 10/40; G21F 7/06; H05K 9/0071

(57) ABSTRACT

Aspects of the present disclosure are directed to mitigating qubit decoherence in quantum circuitry in a target area. Using electromagnetic circuitry having coiled circuitry and being coupled to a structure in an elevated position relative to the target area, an electromagnetic field is generated over the target area by driving current through the coiled circuitry. The electromagnetic field may be used to divert radiation propagating in a direction toward the target area, therein electromagnetically shielding the target area and mitigating qubit decoherence in the quantum circuitry.

### OVERVIEW

Various technologies rely on quantum bits (qubits), which can provide powerful computational functions. Such technologies may require or benefit from long coherence times and high-fidelity operations. However, ionizing radiation from environmental radioactive materials and cosmic rays may limit coherence times in applications such as those involving superconducting qubits. Observations reveal natural radioactivity and cosmic ray muons produce correlated noise that limits QC qubit coherence time in the millisecond range.

Mitigating or preventing such radiation from reaching technologies utilizing quantum bits can be challenging. For instance, placing quantum circuitry underground can block radiation, but can be impractical and expensive. These and other matters have presented challenges to quantum technologies, for a variety of applications.

### SUMMARY

Various example embodiments are directed to radiation shields, related methods, their application and their manufacture. Such embodiments may be useful for shielding quantum circuitry.

Aspects of the present disclosure are directed to methods for mitigating qubit decoherence in quantum circuitry in a target area. Using electromagnetic circuitry having coiled circuitry and being coupled to a structure in an elevated position relative to the target area, an electromagnetic field is generated over the target area by driving current through the coiled circuitry. The electromagnetic field may be used to divert radiation propagating in a direction toward the target area, therein electromagnetically shielding the target area and mitigating qubit decoherence in the quantum circuitry.

Another embodiment is directed to an apparatus having a structure with a base and structural components extending upward from the base, and electromagnetic circuitry coupled to the structure in an elevated position relative to the base. The electromagnetic circuitry may include coiled circuitry and be configured to divert radiation, which is propagating in a direction toward a target area adjacent the base, by generating an electromagnetic shield in response to current being driven through the coiled circuitry, and therein electromagnetically shielding the target area.

The above discussion/summary is not intended to describe each embodiment or every implementation of the present disclosure. The figures and detailed description that follow also exemplify various embodiments.

### BRIEF DESCRIPTION OF THE FIGURES

Various example embodiments may be more completely understood in consideration of the following detailed description and in connection with the accompanying drawings, in which:

FIG. 1 shows an electromagnetic shield apparatus with a quantum computing target area, in accordance with one or more embodiments; and

FIG. 2 shows an electromagnetic shield apparatus with a quantum computing target area located below ground level for passive shielding, as may be implemented in accordance with various embodiments;

FIG. 3 shows an electromagnetic shield apparatus with a single electromagnetic coil, in accordance with various embodiments;

FIG. 4 shows an electromagnetic coil apparatus with cooling, as may be implemented in accordance with various embodiments:

FIG. 5 shows an electromagnetic coil apparatus with cooling, as may be implemented in accordance with various embodiments;

FIG. 6 shows an electromagnetic shield apparatus with stacked electromagnetic coils, in accordance with an embodiment;

FIG. 7 shows an electromagnetic shield apparatus with adjacent electromagnetic coils, in accordance with an embodiment;

FIG. 8 shows an electromagnetic shield apparatus with parallel electromagnetic coils, in accordance with an embodiment;

FIG. 9 shows an electromagnetic shield apparatus with electromagnetic coils arranged in different planes, in accordance with an embodiment;

FIG. 10 shows an electromagnetic shield apparatus with elongated electromagnetic coils coupled on a roof or top portion of a structure, as may be implemented in accordance with various embodiments;

FIG. 11 shows an electromagnetic coil, as may be implemented in accordance with various embodiments;

FIG. 12 shows an electromagnetic shield apparatus with electromagnetic coils forming a dome shape, as may be implemented in accordance with various embodiments;

FIG. 13 shows dome-shaped electromagnetic shield apparatuses coupled on a roof or top portion of a structure, as may be implemented in accordance with various embodiments;

FIG. 14 shows a dome-shaped electromagnetic shield apparatus over a structure, as may be implemented in accordance with various embodiments;

FIG. 15 shows an electromagnetic shield apparatus having a dome with horizontal coils, as may be implemented in accordance with various embodiments; and

FIG. 16 shows dome-shaped electromagnetic field components having horizontal coils and located on the roof or top of a structure, as may be implemented in accordance with various embodiments.

While various embodiments discussed herein are amenable to modifications and alternative forms, aspects thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the disclosure including aspects defined in the claims. In addition, the term “example” as may be used throughout this application is by way of illustration, and not limitation.

### DETAILED DESCRIPTION

Aspects of the present disclosure are believed to be applicable to a variety of different types of articles of manufacture, apparatuses, systems and methods involving electromagnetic shielding. In certain implementations, aspects of the present disclosure have been shown to be beneficial when used in the context of shielding sensitive equipment, such as quantum computers and/or other radiation-sensitive equipment or objects in a target area. Such approaches may, for instance, involve an electromagnetic coil elevated relative to a target area and a direction of incoming radiation such that the target area is shielded from the incoming radiation. In certain implementations, electromagnetic coils are integrated with a quantum computing facility's infrastructure. While not necessarily so limited, various aspects may be appreciated through a discussion of examples using such exemplary contexts.

As may be implemented with various example embodiments, an active magnetic shield is used to mitigate the effect of ionizing radiation associated with radiation, such as cosmic radiation. The active magnetic shield may include superconducting coils that cast a cosmic ray shadow over a target area, such as a quantum computing facility, by utilizing a tower or other type of structure to mount the superconducting coils in an elevated position. This may be carried out in conjunction with passive shielding, such as by locating equipment below ground level and/or using other passive shielding such as lead, to protect from undesirable radiation such as environmental gamma rays. In some implementations, the technology is miniaturized to shield smaller quantum computers, such as mobile, portable or even handheld devices. These approaches may be utilized to generate a protective magnetosphere around physical qubits, preventing cosmic radiation interference.

Various embodiments are directed to increasing superconducting qubit coherence times (or mitigating reduction in such coherence times), such as by diverting cosmic ray muons. These approaches may facilitate the development and operation of fault-tolerant quantum computers. In connection with such approaches, it has been recognized/discovered that muon flux can be reduced below 10-100 GeV in a confined region, and decrease decoherence rates by a factor of over 30000.

A method-based embodiment is directed to methods for mitigating qubit decoherence in quantum circuitry located in a target area using electromagnetic circuitry having coiled circuitry and coupled to a structure in an elevated position relative to the target area. Current is driven through the coiled circuitry to generate an electromagnetic field that diverts radiation propagating in a direction toward the target area. In this context, the target area is electromagnetically shielded (e.g., reducing muon flux below 100 GeV) and qubit decoherence within the quantum circuitry can be mitigated or prevented. This may involve, for example, casting a cosmic ray shadow over the target area by diverting cosmic ray muons and therein shielding the target area and quantum circuitry from ionizing radiation. In addition, the coiled circuitry may be cooled while the electromagnetic shield is being generated, for instance using a pump and cooling coils located to facilitate heat transfer from the coiled circuitry. Passive shielding may also be used to augment the radiation shielding effected via the electromagnetic coils, for instance as may include passive components coupled to the structure in an elevated position.

In a particular embodiment, the electromagnetic circuitry is coupled to the structure in the elevated position, relative to a base of the structure located in the target area and anchored thereat, for instance by anchoring into ground or onto a building. The electromagnetic field may be used to divert radiation propagating in a direction that extends from the electromagnetic circuitry toward the base of the structure.

In a further embodiment, the electromagnetic circuitry includes respective coils arranged in different positions relative to one another. Each of the respective coils may be used to divert radiation propagating in a direction different from radiation diverted by another one of the respective coils. Each coil may thus be utilized to shield different portions of the target area relative to portions of the target area shielded by other ones of the respective coils.

Another embodiment is directed to an apparatus having a structure with a base and structural components extending upward from the base, and electromagnetic circuitry coupled to the structure in an elevated position relative to the base. The electromagnetic circuitry may include coiled circuitry operable to divert radiation, and the apparatus may include a power supply that drives the current through the coiled circuitry. For instance, radiation propagating in a direction toward a target area adjacent the base may be diverted by generating an electromagnetic shield as noted herein, such as by driving current through the coiled circuitry. This approach may thus electromagnetically shield the target area (e.g., reducing muon flux below 100 GeV). The electromagnetic circuitry may thus mitigate qubit decoherence in quantum circuitry in the target area, by generating an electromagnetic field over the target area and using the electromagnetic field to divert ionizing radiation propagating towards the target area. Such approaches may involve casting a cosmic ray shadow over the target area by diverting cosmic ray muons and therein shielding the target area from ionizing radiation. The apparatus may further include passive shielding components.

The coiled circuitry may be arranged in a variety of manners, and on a variety of structures such as on a tower or on the roof of a building, with various methods being implemented accordingly. In some implementations, the coiled circuitry includes coils arranged in a semicircular arrangement. In particular embodiments, the coiled circuitry includes a plurality of respective coils having different dimensions with the coils being collectively arranged in a dome-type arrangement.

A more specific embodiment is directed to coils arranged horizontally and stacked vertically relative to others of the coils. For instance, the respective coils may include first and second stacks of coils forming nested domes. The first stack of coils form a first dome-type arrangement, with each coil being arranged horizontally and extending in parallel with other ones of the coils in the first stack. The second stack of coils forms a second dome-type arrangement in which each coil is arranged horizontally and extends in parallel with other ones of the coils in the first stack.

In some embodiments, the apparatus includes a coolant supply that carries coolant and is coupled relative to the coiled circuitry to cool the coiled circuitry while the electromagnetic shield is being generated. This may include, for example, a heat exchanger, coils and/or other componentry. The apparatus may further include a pump that pumps the coolant through the coolant supply. These aspects may be included with one or more apparatuses as depicted in the figures.

In a particular embodiment, the electromagnetic circuitry includes respective coils arranged in different positions relative to one another. Each coil operates to divert radiation propagating in a direction different from radiation diverted by another one of the respective coils. As such, each coil shields a different portion of the target area relative to a portion of the target area shielded by the other one of the respective coils.

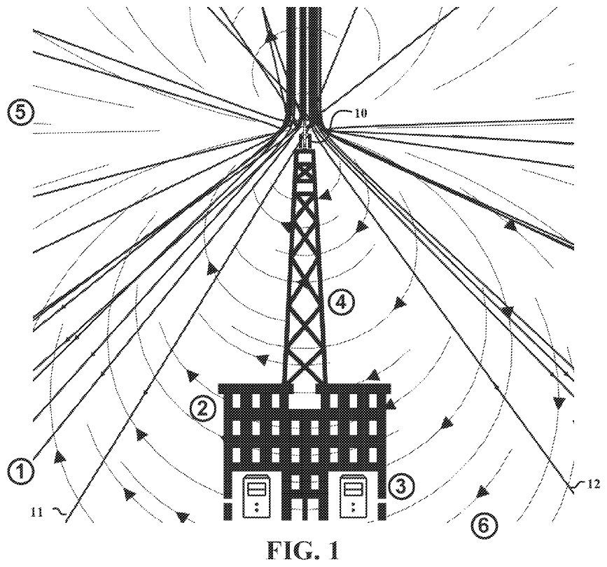

Turning now to the figures, various figures use similar reference numbers to refer to similar components, and may be implemented as such. Beginning with FIG. 1, an electromagnetic shield apparatus is shown with a quantum computing target area, in accordance with one or more embodiments. The apparatus includes a magnetic tower 4 having electromagnetic circuitry 10 elevated over a quantum computing center 2 housing quantum computers 3. The electromagnetic circuitry 10 generates a magnetic field, depicted by magnetic field lines 5, which deflect cosmic-ray muons 1 and cast a muon shadow 6, generally represented by lines 11 and 12.

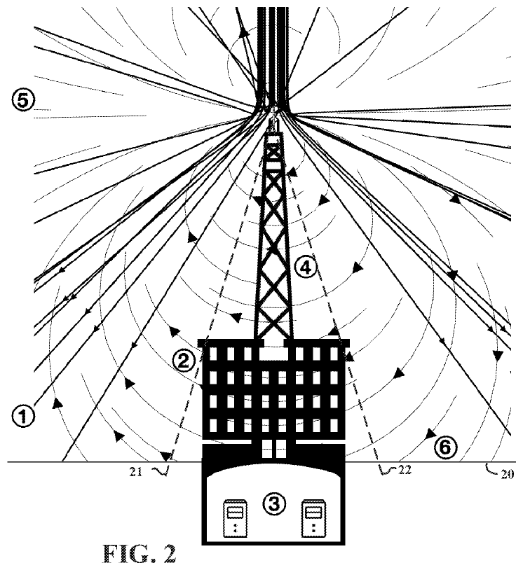

FIG. 2 shows an electromagnetic shield apparatus with a quantum computing target area located below ground level (20) for passive shielding, in accordance with various embodiments. Similar to FIG. 1, a magnetic tower 4 has electromagnetic circuitry, which operates here in connection with the passive shielding provided by the underground location of computers 3, to provide electromagnetic shielding. Additional passive shielding elevated with respect to quantum circuitry may be added to augment electromagnetic circuitry active shielding. For instance, 5 cm of lead shell may reduce gamma-rays by a factor of 300, and 6 cm of lead shell may reduce gamma-rays by a factor of 1000. Further, the muon shadow 6 may be tailored to the size and location of the underground location of the computers, for instance as shown by dashed lines 21 and 22.

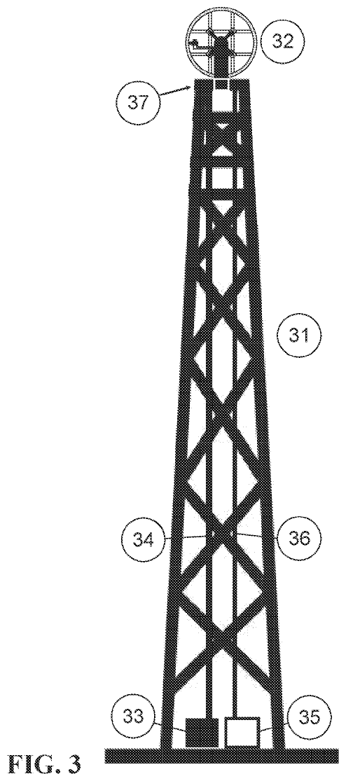

FIG. 3 shows an electromagnetic shield apparatus including a tower 31 and a single electromagnetic coil 32 securely anchored on top, in accordance with various embodiments. A cryogen storage and compressor component 33 stores cryogenic coolant and pumps that coolant via piping 34 to cycle cryogenic fluid through the coil 32. A power supply 35 provides power for the electromagnetic coil 32 via power cable 36. A quenching monitoring and protection system 37 may further be included to facilitate safe operation of the apparatus.

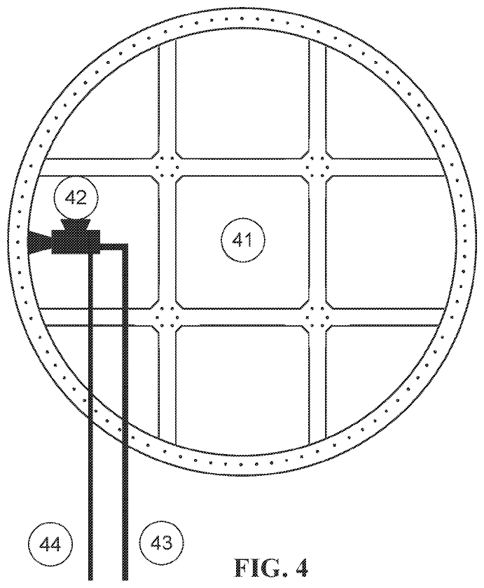

FIG. 4 shows an electromagnetic coil apparatus with cooling, in accordance with various embodiments. The apparatus includes a coil support structure 41 that may include a coil mechanical casing to counteract hoop and folding stresses from magnetic forces, and a cryocooler pump and temperature monitoring component 42. Piping 43 cycles cryogenic fluid and a power cable 44 provides power for the cryocooler. The coil support structure may utilize an Aluminum 6061-T6 alloy for strength, include I-beam ribs to support coil position, and utilize titanium bolts for strength and magnetic properties. A Kevlar composite laminate enclosure may be utilized for additional hoop stress resistance, and an insulation sheet may be provided to insulate from external heat. The coil apparatus may be utilized in connection with other embodiments depicted in the other figures.

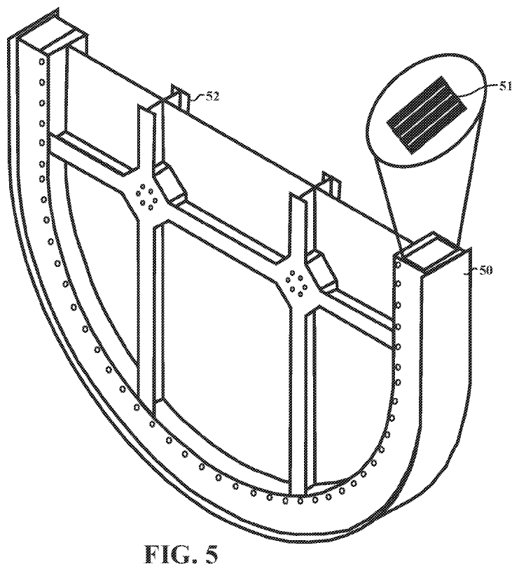

FIG. 5 shows an electromagnetic coil apparatus with cooling, in accordance with various embodiments. The apparatus includes a frame 50 that may utilize heat transfer ribs as depicted in the inset at 51. I-beam type supports 52 add strength. High-temperature superconducting tape may be wrapped around the frame, which may be implemented with a ribbed Aluminum frame, Kevlar laminate and heat insulator. High-purity aluminum tape may be wrapped between each strand of superconducting tape to increase thermal conduction from the cryocooler. The coil casing may resist mechanical stress and cable strain from magnetic forces

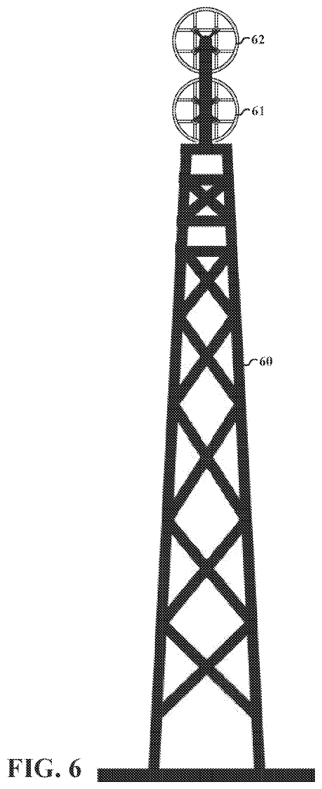

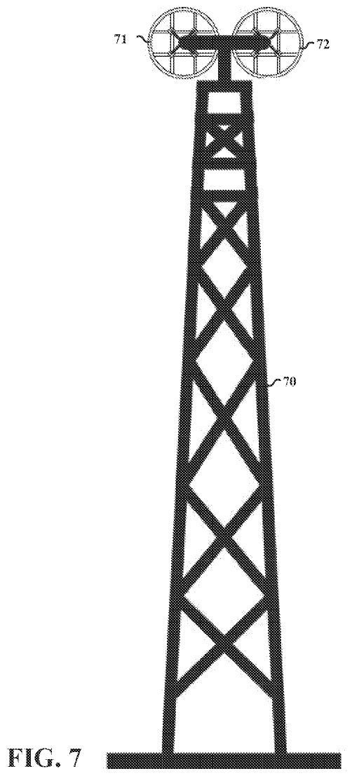

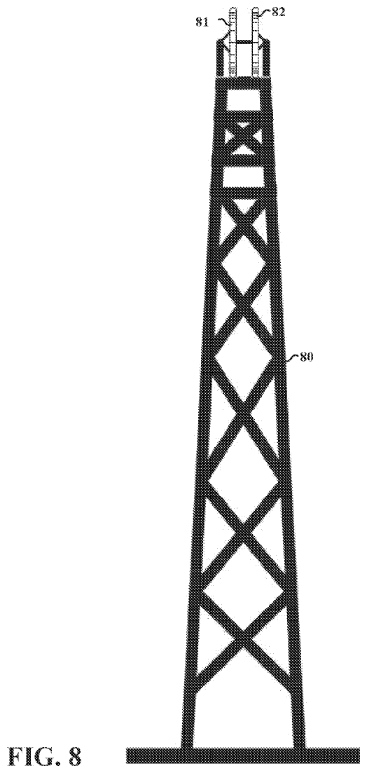

As discussed herein, a variety of electromagnetic coil configurations may be implemented to suit particular embodiments. In this context, FIGS. 6-9 depict towers with coils on towers in various arrangements. FIG. 6 shows an electromagnetic shield apparatus having a tower 60 with stacked electromagnetic coils 61 and 62, in accordance with an embodiment. FIG. 7 shows an electromagnetic shield apparatus with tower 70 and adjacent electromagnetic coils 71 and 72, in accordance with another embodiment. FIG. 8 shows an electromagnetic shield apparatus having a tower 80 and with parallel electromagnetic coils 81 and 82, in accordance with another embodiment.

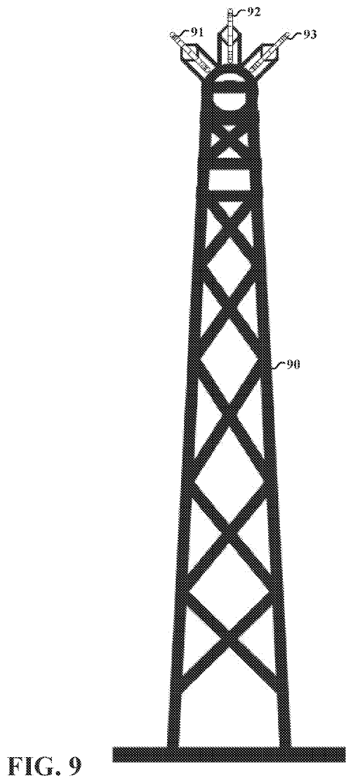

In some implementations, coils are arranged in respective orientations to shield radiation from a particular direction and/or to create specific cosmic shadow configurations. For instance, FIG. 9 shows an electromagnetic shield apparatus having a tower 90 and electromagnetic coils 91, 92 and 93 arranged in different planes, in accordance with another embodiment. Fewer or more coils may be arranged in similar or different orientations. This may be used to widen the magnetic field above a target area, and enhance shielding.

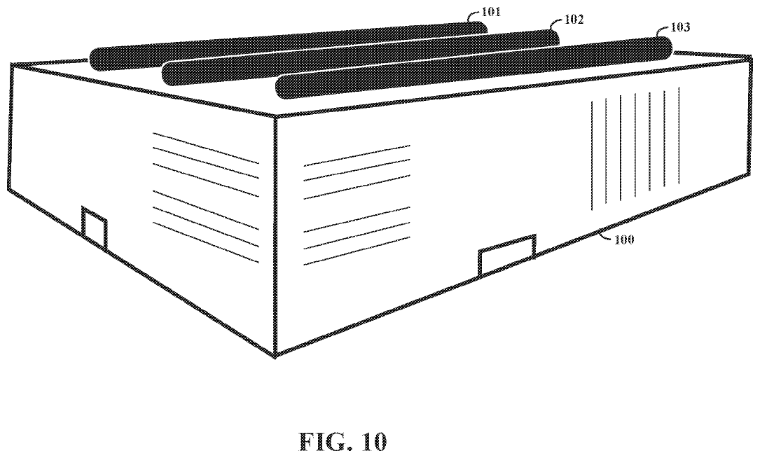

As discussed herein, various types of structures may be used to elevate electromagnetic coils, in addition to towers as noted in the figures discussed above. For instance, FIG. 10 shows an electromagnetic shield apparatus with elongated electromagnetic coils 101, 102 and 103 coupled on a roof or top portion of a structure 100, in accordance with various embodiments. For instance, elongated coils may be installed directly on a roof of a quantum computing building.

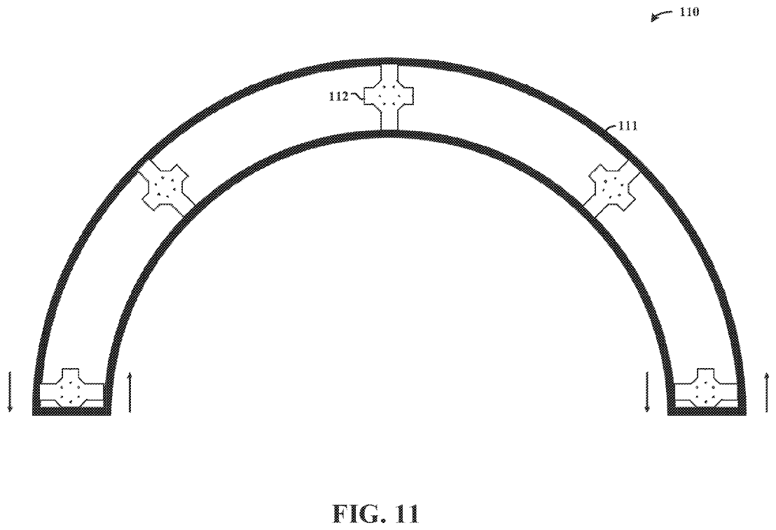

FIG. 11 shows an electromagnetic coil 110, as may be implemented in accordance with various embodiments. The electromagnetic coil 110 includes a conductor 111 that flows current in the direction shown by arrows. Support structures maintain and support the conductor 111, with structure 112 labeled by way of example. Such a coil may be implemented with other such coils of similar and/or different sizes, for example in an arrangement similar to that shown with FIG. 10, coupled on a roof or top portion of structure 100.

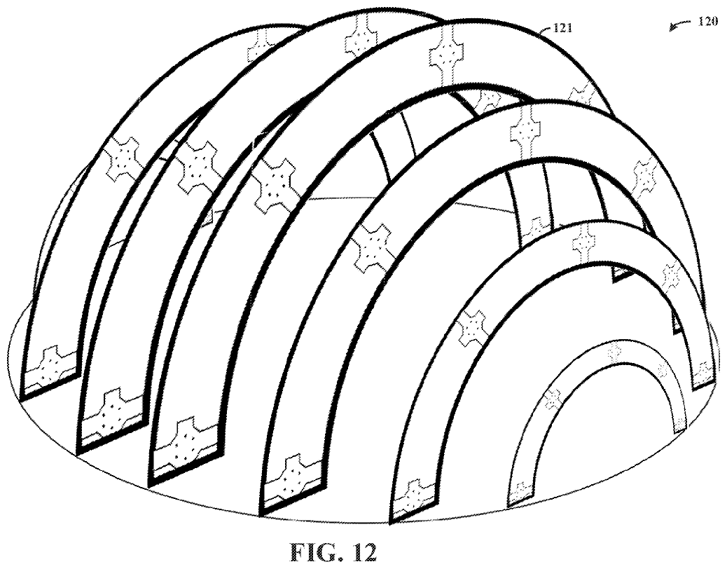

FIG. 12 shows an electromagnetic shield apparatus 120 with electromagnetic coils (including coil 121) forming a dome shape, as may be implemented in accordance with various embodiments. The coils in apparatus 120 may be implemented using coils similar to that discussed in connection with FIG. 11, with varied sizing as shown in FIG. 12 to create a dome shape, with each coil parallel (or about parallel) to the others. The apparatus 120 can be deployed in a variety of arrangements, for example to partially enclose a structure, or on top of/the roof of a building. A quantum computing server may be located at a central area underlying the dome shape apparatus 120.

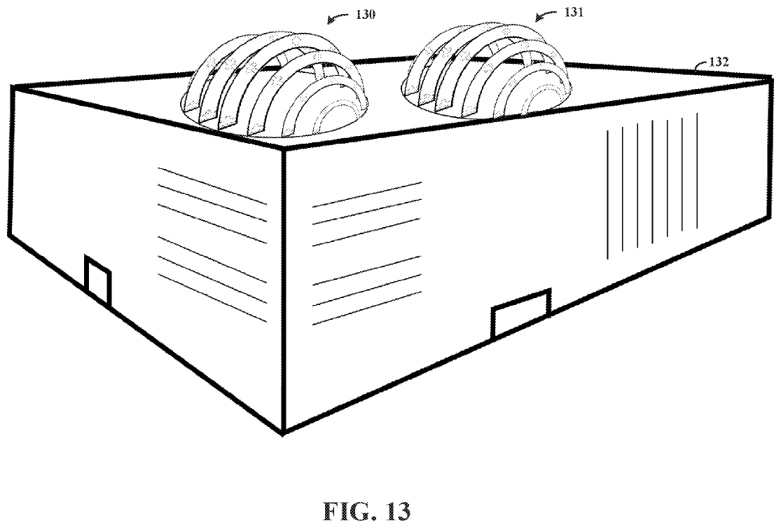

FIG. 13 shows dome-shaped electromagnetic shield apparatuses 130 and 131 coupled on a roof or top portion of a structure 132, as may be implemented in accordance with various embodiments. The dome-shaped electromagnetic shield apparatuses 130 and 131 may, for example, be implemented utilizing a structure similar to that shown in and described in connection with FIG. 12, with coils being coupled to and above a base (structure 132).

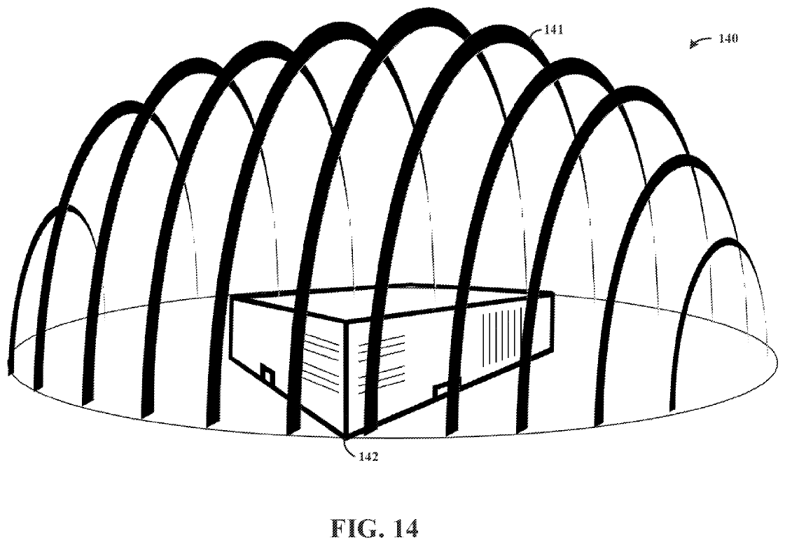

FIG. 14 shows a dome-shaped electromagnetic shield apparatus 140 having a plurality of coils (including 141), and located over a structure 142, as may be implemented in accordance with various embodiments. The apparatus 140 may include individual coils similar to that shown in FIG. 12 and/or in FIG. 13.

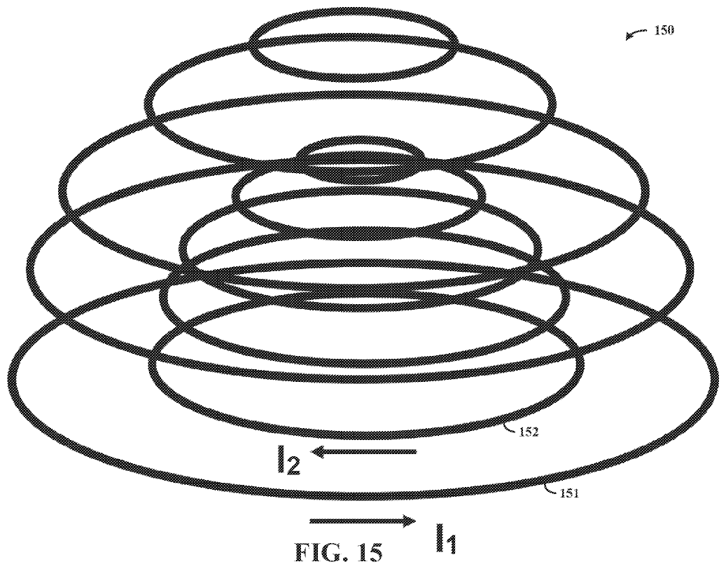

FIG. 15 shows an electromagnetic shield apparatus 150 having a dome with horizontal coils, as may be implemented in accordance with various embodiments. An outer set 151 of stacked coils flows current (11) in a first direction as shown, and an inner set 152 of stacked horizontal coils flows current (12) in a second direction opposite the first direction, as shown. The respective sets of coils may form nested domes, making up an overall dome as shown. The inner set of coils 152 may operate using current scaled to provide a low magnetic field at the center base of the dome.

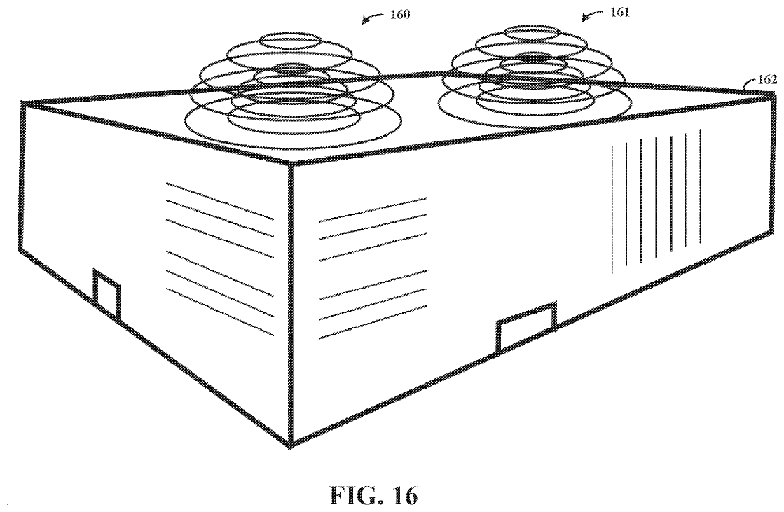

FIG. 16 shows dome-shaped electromagnetic field components 160 and 161 having horizontal coils and located on the roof or top of a structure 162, as may be implemented in accordance with various embodiments. The electromagnetic field components 160 and 161 may be implemented using that shown in FIG. 15, with nested domes as explained above.

The various electromagnetic field structures as shown in the figures and described herein may be operated using a variety of approaches, to pass current through the coils and otherwise operate to provide electromagnetic shielding. For instance, the coils shown in FIGS. 6-16 may be fed by a current supply and/or cooled with cooling componentry such as that described in connection with FIG. 3.

Based upon the above discussion and illustrations, those skilled in the art will readily recognize that various modifications and changes may be made to the various embodiments without strictly following the exemplary embodiments and applications illustrated and described herein. For example, fewer or additional coils may be used, and coils may be arranged at different orientations. Further, a variety of structures may be used to elevate coils. In addition, orientation may be adjusted such that embodiments referring to a direction may be modified relative to radiation direction rather than, for example, toward ground (e.g., a cosmic shadow may be created horizontally relative to that depicted in FIG. 1). In addition, electromagnetic fields may be generated using different types of circuitry, as may include different shapes than that characterized herein. Such modifications do not depart from the true spirit and scope of various aspects of the invention, including aspects set forth in the claims.

What is claimed is:

1. A method for mitigating qubit decoherence in quantum circuitry in a target area, the method comprising:
using electromagnetic circuitry having coiled circuitry and being coupled to a structure in an elevated position relative to the target area, generating an electromagnetic field over the target area by driving current through the coiled circuitry; and
using the electromagnetic field to divert radiation propagating in a direction toward the target area, therein electromagnetically shielding the target area and mitigating qubit decoherence in the quantum circuitry.

2. The method of claim 1, wherein using electromagnetic circuitry having coiled circuitry includes using circuitry having coils arranged in a semicircular arrangement.

3. The method of claim 1, wherein using electromagnetic circuitry having coiled circuitry includes using circuitry having a plurality of respective coils having different dimensions and being collectively arranged in a dome-type arrangement.

4. The method of claim 3, wherein the plurality of respective coils are arranged horizontally and stacked vertically relative to others of the coils.

5. The method of claim 3, wherein the plurality of respective coils include:
a first stack of coils forming a first dome-type arrangement, each coil being arranged horizontally and extending in parallel with other ones of the coils in the first stack; and
a second stack of coils forming a second dome-type arrangement, each coil being arranged horizontally and extending in parallel with other ones of the coils in the first stack, the second stack of coils being nested within the first stack of coils.

6. The method of claim 1, wherein:
using the electromagnetic circuitry includes coupling the electromagnetic circuitry to the structure in the elevated position, relative to a base of the structure located in the target area and anchored thereat, and
using the electromagnetic field to divert radiation propagating in a direction toward the target area includes diverting radiation propagating in a direction that extends from the electromagnetic circuitry toward the base of the structure.

7. The method of claim 1, wherein generating the electromagnetic field includes casting a cosmic ray shadow over the target area by diverting cosmic ray muons and therein shielding the target area and quantum circuitry from ionizing radiation.

8. The method of claim 1, further including cooling the coiled circuitry while the electromagnetic shield is being generated.

9. The method of claim 1, wherein:
the electromagnetic circuitry includes respective coils arranged in different positions relative to one another;
generating the electromagnetic field includes, for each of the respective coils, diverting radiation propagating in a direction different from radiation diverted by another one of the respective coils; and
using the electromagnetic field includes shielding a different portion of the target area relative to a portion of the target area shielded by the other one of the respective coils.

10. An apparatus comprising:
a structure having a base and structural components extending upward from the base; and
electromagnetic circuitry coupled to the structure in an elevated position relative to the base, the electromagnetic circuitry including coiled circuitry and being configured to divert radiation, which is propagating in a direction toward a target area adjacent the base, by generating an electromagnetic shield in response to current being driven through the coiled circuitry, and therein electromagnetically shielding the target area.

11. The apparatus of claim 10, wherein the coiled circuitry has coils arranged in a semicircular arrangement.

12. The apparatus of claim 10, wherein the coiled circuitry includes a plurality of respective coils having different dimensions and being collectively arranged in a dome-type arrangement.

13. The apparatus of claim 12, wherein the plurality of respective coils are arranged horizontally and stacked vertically relative to others of the coils.

14. The apparatus of claim 12, wherein the plurality of respective coils include:
a first stack of coils forming a first dome-type arrangement, each coil being arranged horizontally and extending in parallel with other ones of the coils in the first stack; and
a second stack of coils forming a second dome-type arrangement, each coil being arranged horizontally and extending in parallel with other ones of the coils in the first stack, the second stack of coils being nested within the first stack of coils.

15. The apparatus of claim 10, wherein the structure is a building having a base and building structure including a roof extending upward from the base, and wherein the electromagnetic circuitry is coupled to the roof.

16. The apparatus of claim 10, wherein the electromagnetic circuitry is configured to mitigate qubit decoherence in quantum circuitry in the target area, by generating an electromagnetic field over the target area and using the electromagnetic field to divert ionizing radiation propagating towards the target area.

17. The apparatus of claim 10, wherein the electromagnetic circuitry is configured to cast a cosmic ray shadow over the target area by diverting cosmic ray muons and therein shielding the target area from ionizing radiation.

18. The apparatus of claim 10, wherein the electromagnetic circuitry includes a power supply configured to drive the current through the coiled circuitry, further including a coolant supply configured to carry coolant and coupled relative to the coiled circuitry to cool the coiled circuitry while the electromagnetic shield is being generated.

19. The apparatus of claim 10, further including passive shielding configured to shield at least a portion of the target area from environmental gamma rays.

20. The apparatus of claim 10, wherein the electromagnetic circuitry includes respective coils arranged in different positions relative to one another, each of the respective coils being configured to:
divert radiation propagating in a direction different from radiation diverted by another one of the respective coils, and
shield a different portion of the target area relative to a portion of the target area shielded by the other one of the respective coils.
